(19) United States
(12) Patent Application Publication
(10) Pub. No.: US 2011/0318981 A1
(43) Pub. Date: Dec. 29, 2011

(54) COMPOSITE MATERIAL STRUCTURE PROTECTED AGAINST THE EFFECTS OF LIGHTNING

(75) Inventors: Yohann Duval, Rueil Malmaison (FR); Marie-Paule Guillou, Noisy Le Grand (FR); Franck Uhlig, Lognes (FR)

(73) Assignee: EUROPEAN AERONAUTRIC DEFENCE AND SPACE COMPANY EADS FRANCE, Paris (FR)

(21) Appl. No.: 13/139,633

(22) PCT Filed: Dec. 15, 2009
(86) PCT No.: PCT/EP09/67154

§ 371 Date: Sep. 16, 2011

(30) Foreign Application Priority Data
Dec. 15, 2008 (FR) 0858580

(51) Int. Cl. H05K 9/00; B32B 3/10

(52) U.S. Cl. 442/1

(57) ABSTRACT

The invention relates to a part (1) including a structural portion made of an electrically insulating or low-conductive composite material (2), such that a piece containing glass fibres or carbon fibres is protected against the accumulation of electric charges or impact from lightning by a metallisation of the surface to be protected. The metallisation includes a screen (31) of an electrically conductive material covered with a layer of an electrically conductive paint (32). A sizing and priming layer (33) is also provided between the screen and the conductive paint, as well as a finish paint covering the conductive paint (32). The assembly results in a protection against impacts from lightning with a reduced size as compared to traditional metallisations with a metal screen.

The present invention belongs to the field of structures made with composite materials. More particularly, the invention relates to structures made from electrically nonconductive or low-conductive composite materials exposed to lightning impacts during their use.

The invention relates in particular to composite material structures for aircraft.

Among the many families of composite materials, the family of composites comprising fibers of an inorganic material (glass, silica, carbon, etc.) or organic material (aramid, Kevlar®, etc.) maintained in a hard organic matrix (polyester, epoxy, etc.) is widely employed for manufacturing structures due to their mechanical performance, in particular their strength to mass ratio, and/or due to their aptitude for manufacturing complex shapes.

These features and advantages are particularly appreciated for the manufacture of aircraft and, in the context of the present application, composite material means composite materials of this family of materials comprising inorganic or organic fibers maintained in a hard organic matrix.

When composite materials are employed to manufacture aircraft structures subjected to streamline flow outside the aircraft, electrical charges tend to accumulate naturally on the surface of the material due to the insulating or electrically low-conductive nature of these materials.

If special precautions are not observed, these charges are transferred to the ambient air, when the electrical potential differences are locally sufficient due to the accumulated electrical charges, in the form of electrical discharges which generate electromagnetic disturbances that are liable to disturb the operation of the aircraft's electronic systems.

Furthermore, aircraft in flight are frequently subject to impacts of lightning, of which the electrical energy is sufficient to cause local damage to the structure, damage which must be avoided for obvious reasons of integrity of the aircraft and for safety reasons, when the structures concerned are structures required to withstand high forces, called working structures.

For these reasons, it is known how to make the structures of composite material electrically conductive on a surface of these structures subject to streamline flow, and which is also the surface exposed to lightning impacts.

To make an intrinsically insulating or low-conductive composite material structure electrically conductive on the surface, it is known to place electrically conductive metal elements on the surface which is to be made conductive, said conductive metal elements being connected together by a part of composite material to another part of composite material or being connected to a conductive metal structure.

A first known technique consists in placing more or less widely spaced conductive metal bands on the surface of the part of composite material, connected, by at least one of their ends, to a general earth of the aircraft.

The advantage of this solution is that it serves to limit the surface area covered by the conductive material while allowing for significant conductive sections to convey the lightning currents and therefore to preserve the high radioelectric transparency of the composite material structure thus metallized.

This solution of bands called lightning arresters is advantageously employed on aircraft radomes, but is difficult to implement and has the drawback of not protecting the entire surface of the part, in particular when radioelectric transparency is not required.

A second known technique consists in covering the whole surface of the composite material structure to be protected with a wire mesh made from an electrically conductive metallic material.

Such a wire mesh is usually made from bronze or copper, in particular due to the electrical conductivity properties of these materials, and for reasons of corrosion resistance, either by a conventional wire weaving process or by a drawing process from a plate prepared to obtain a wire mesh by deployment.

These wire mesh are deposited on the surface of the part by various techniques, for example deposited on the surface of the part during manufacture before curing by polymerization of the matrix of the composite material.

Due to the currents associated with lightning impacts, in particular close to the point of the structure where the impact occurs, the wire mesh must have sufficient conductive cross sections, which lead to wire mesh that are on the one hand heavy (generally 150 to 300 g/m2 on an aircraft structure, or about 1000 kg for the protection of a long-haul jumbo jet) and, on the other hand, are detrimental to the surface condition of the structure thus treated, whereof the aerodynamic aspect and the aesthetic aspect require, for their protection, a sufficiently thick sizing layer and a finish paint layer of about 100 μm (E10-4 m), which are penalizing in terms of cost and weight.

Furthermore, such wire mesh, which are relatively stiff, have the drawback of complex application, in particular due to the shapes of the structures to be covered and the interference with the composite material manufacturing processes.

It is precisely the object of the present invention to define a composite material structure that is effectively protected against the effects of lightning, and which avoids the accumulations of electrical charges on its surface, with a reduced mass penalty compared to the known solutions and having at least equivalent performance with regard to protection against the effects of lightning impacts.

According to the invention, the protected part comprises a structural portion of electrically insulating or low-conductive composite material such as parts made from inorganic or organic fibers, for example glass fibers, aramid fibers or carbon fibers, maintained in a hard organic matrix, for example epoxy.

On the surface of the structural portion, at least on the side of the part liable to be exposed to accumulations of electrical charges or to lightning impacts, the part is covered, at least in the zones that require protection, by a wire mesh made with an electrically conductive material, attached directly to the surface of the structural portion, and comprises an electrically conductive paint layer deposited so that the wire mesh is located between the structural portion of composite material and the electrically conductive paint layer.

The paint forms a continuous conductive layer which serves to disperse the arc bottom during a lightning impact so that the lightning current is conveyed in the conductive wire mesh with lower current densities in comparison to a situation in which the lightning strikes the conductive wire mesh directly, even passing through an insulating paint layer covering the conductive wire mesh. It is thereby possible to reduce the surface density of the wire mesh of electrically conductive material in comparison with the conventional metallization that employs this type of wire mesh.

To improve the final surface condition of the part and to protect the wire mesh, the part comprises, if necessary, between the wire mesh and the electrically conductive paint layer, a sizing and/or primer layer for protecting the wire mesh, said primer layer in particular filling the recessed volumes liable to subsist between the conductive portions of the wire mesh after the wire mesh is layered on the structural portion.

Owing to their good electrical conduction properties, the wire mesh is advantageously made by means of a metal wire mesh made from bronze, copper or copper alloy, or even from aluminum or aluminum alloy.

The application of the invention serves to limit the quantity of metal used to form the conductive wire mesh. In practice, for an aircraft structure, the composite structure is protected satisfactorily against the effects of lightning with a conductive wire mesh surface density of 30 to 100 g/m2 and preferably a surface density of 70±10 g/m2, in other words, on average a weight penalty devoted to the metallization of the composite structures that is two to three times lower for a metallization of equivalent performance, or even less.

Effective protection is obtained in particular when the electrical conductivity of the electrically conductive paint layer is at least 0.0001 Siemens/m.

To protect the electrically conductive paint and to obtain the desired surface condition, the protected surface is covered with a finish paint layer preferably having an average thickness of 20±5 μm.

The selection of the conduction properties suitable for the conductive wire mesh and for the electrically conductive paint serves to produce a paint layer of which the cumulative thickness of the electrically conductive paint layer and the finish paint layer is substantially identical to a single protective paint layer, that is to say, 100±20 μm on average, and therefore does not penalize the product made in particular in terms of paint mass.

The detailed description of exemplary embodiments is provided with reference to the figures which show:

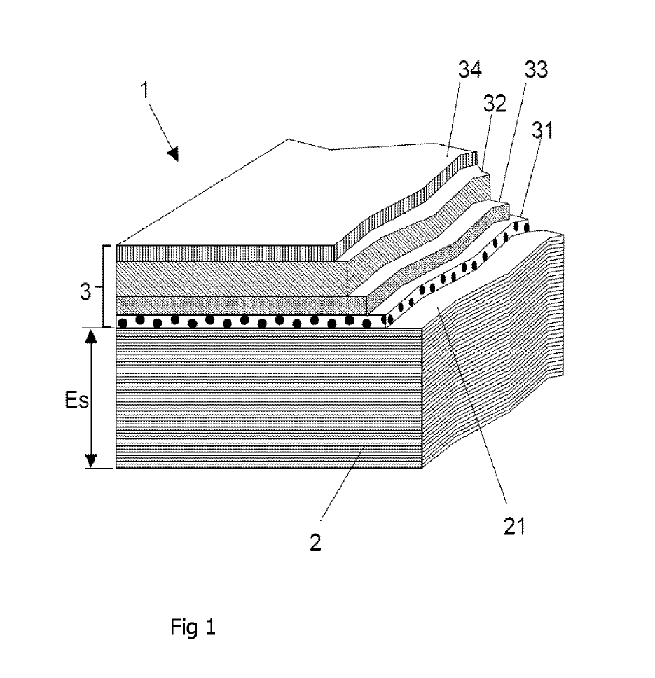

FIG. 1: schematically on a partial cutaway perspective view of a cross section, the various layers forming a part of composite material according to the invention;

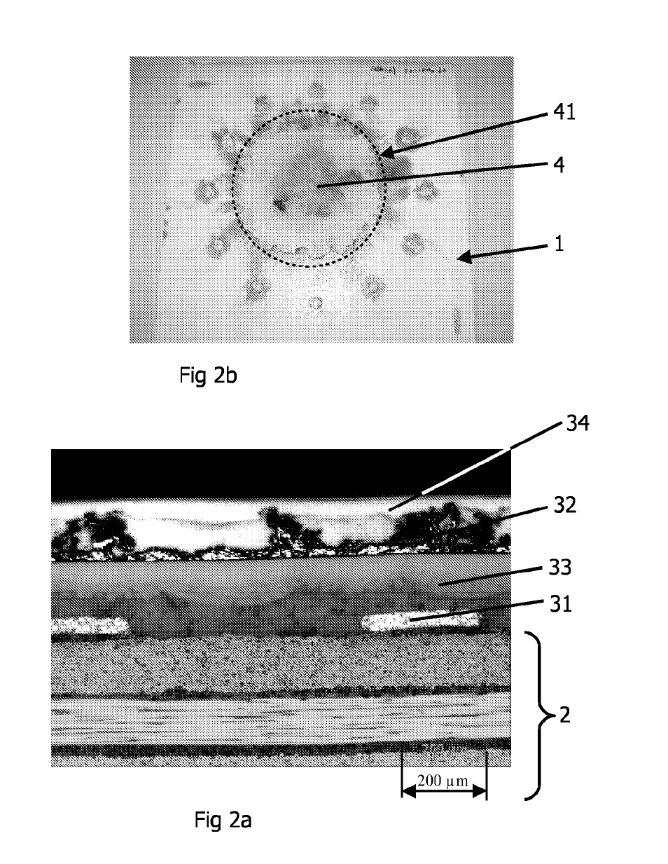

FIG. 2a: a photograph of a cross section of a test specimen (micro-cross section) in FIG. 2a showing the various layers on the side of a protected surface of the composite material according to the invention;

FIG. 2b: a photograph of the protected surface of the test specimen after receiving a lightning impact.

A structural part 1 of composite material according to the invention mainly comprises a structural portion 2 having a structural thickness Es comprising inorganic or organic fibers maintained in a hard organic matrix.

A portion of said structural part is shown in FIG. 1. FIG. 1 shows a locally flat part for illustration without limiting the invention.

Such a structure is known in particular in aeronautical applications, for which a favorable structural strength to mass ratio is desired.

For example, such a structure comprises stacked plies of glass, Kevlar® or carbon fibers, woven or unidirectional, maintained in a matrix of a polymer material such as aramid.

In another embodiment, not shown, the structure comprises in its thickness Es a cellular, foam or honeycomb structure for example, between two coatings provided by fibers maintained in a matrix, such a structure externally having similar properties with regard to the electrical problems associated with lightning to a structure of composite material without a cellular core.

Also in a manner known per se, the structure is shaped to match the part during a shaping process before hardening by polymerization of the matrix material, in the case of thermoset matrices, or during a shaping process at a temperature at which the matrix is in a plastic state, in the case of thermoplastic matrices.

Depending on each case, such a part comprises metal portions (not shown) and/or perforations (not shown) in particular for the fastening needs of the part 1.

According to its intended use, such a part is, for example, a part called a structural part subject to high forces, approximately similar to the limit conditions of use such as the structural strength of the part, for example a fuselage skin panel or an airfoil, or even a part called a secondary part, such as a fairing, for example an aircraft wing root fairing.

The part 1 further comprises a surface layer 3 called metallization layer on a surface 21, called outer surface, of the structural portion 2 on one side of said part on which electrical charges are liable to accumulate and/or an electrical arc, generated in particular by lightning, is liable to occur.

The surface, or the portion of the surface, of the part 1 on the side of which said metallization layer 3 is located, is called the protected surface. In the case of aircraft, it corresponds in particular to the surface of the part on the outside of the aircraft, that is to say, the surface subject to streamline flow.

The metallization layer 3 itself comprises, on the one hand, a first conductive layer 31 formed by an electrically conductive wire mesh covering the outer surface 21 of the protected structural portion of the part and secured directly to said outer surface and, on the other hand, a second conductive layer 32 formed by an electrically conductive paint covering the first conductive layer 31.

The outer surface 21 is not necessarily covered entirely by the metallization, and certain zones which are exposed little or not at all to lightning hazard may not be metallized, or metallized by other means, the description being limited to a portion of the metallized outer surface 21 according to the principle of the invention.

Electrically conductive paints are known in general and consist for example of paints containing conductive particles.

In such an arrangement, the second conductive paint layer 32 cannot by itself guarantee sufficient conduction to dissipate the lightning currents in the case of lightning impact, but said second conductive paint layer, due to its low local surface resistance, serves to disperse the arc bottom of the lightning around the impact point that is sufficient to distribute the current over an area such that current surface densities are reduced on the protected surface.

In a preferred embodiment, an electrically conductive paint having an electrical conductivity of 0.0001 Siemens/m or higher is selected.

Owing to these reduced current surface densities, the lightning current can be dispersed effectively by the first conductive layer 31 without the need to provide an electrically conductive wire mesh as dense as in conventional protection, since the electrically conductive wire mesh, whose role is to convey the electrical charges and to conduct the electrical currents generated by the lightning arc, is consequently no longer subjected to current densities which are as high as in the conventional metallization principles employing a conductive wire mesh.

Thus the wire mesh is made more lightweight by the use of thinner electrically conductive wires and/or with a looser network wire mesh.

The wire mesh is made, for example, by weaving conductive wires or by a process of drawing and deployment of a conductive sheet in which notches have previously been cut.

Advantageously, the wire mesh is made from conductive metal with a surface density of 30 to 100 g/m2, preferably of 70±10 g/m2, a density as low as 30 g/m2 having been demonstrated to be effective.

The wire mesh of the first conductive layer 31 is attached directly to the outer surface 21 of the structural layer 2 without using an intermediate separator such as a sheet material, in a similar manner to the bronze wire mesh used to metallize the surfaces of composite panels in aeronautical manufacture.

In one method, when the structure of the part of composite material has been produced, the wire mesh is bonded to the outer surface 21 by means of a resin compatible with the composite material of the part 1. This method adds a step in the manufacture of the part, a step that is carried out on a hard part having a shape similar to its final shape.

Another method consists in placing the wire mesh during a step of manufacture of the part by considering the wire mesh as an outer ply of the composite material structure placed on the outer surface 21.

If the part is made with a resin hardened in a hot polymerization step (curing of the thermoset matrix), the wire mesh is layered on the part on the side of the outer surface before the curing step and is secured to the outer surface of the part during the curing step, during which the plies of composite material are compressed against each other in a known manner.

If the part is made with a material having a thermoplastic matrix, the wire mesh is placed on the part, before or after shaping, on the outer surface 21 and adheres to the part on said outer surface under the effect of a pressure applied when the temperature of the resin corresponds to the temperature at which the resin enters a plastic state, either simultaneously with a step of shaping and compacting the thermoplastic plies, or during a subsequent separate step.

In a preferred embodiment, when the irregularities of the surface texture persist after the wire mesh is attached, a primer layer 33 is deposited on the first electrically conductive layer 31 to prepare the adhesion of the conductive paint layer 32 and, in particular when the protected surface is visible, an outer finish layer 34 with a conventional paint provides protection of the electrically conductive paint, an improved final surface condition and the decoration of the structure.

Preferably, the thickness of the outer finish paint layer 34 is reduced to the minimum, advantageously to about 20 μm, typically 20±5 μm on average, which is made feasible by the electrically conductive paint layer 32 which also likewise has the physicochemical behavior of a paint.

As in the case of a conventional paint for protecting a metal structure, the finish paint layer 34 may be insulating, said layer being traversed by the lightning currents near the lightning strike point and, due to its low thickness, has a lower resistance than a conventional paint that is about five times thicker.

Advantageously, the cumulative thicknesses of the second conductive paint layer 32 and the outer finish paint layer 34 are lower than or substantially equal to the thickness of a conventional protection and finish paint layer, that is to say, about 100±20 μm on average.

It is also possible, in applying the solution proposed by the invention, to select, for the manufacture of the electrically conductive material wire mesh 31, a less efficient metallic material than copper with regard to electrical conduction, but a lighter one, such as an aluminum alloy, insofar as the potential corrosion problems are solved by this choice of the materials or by suitable anticorrosion treatment.

The invention therefore serves to produce a structure protected against the effects of lightning with a lower surface protection mass in comparison with known protection systems, by distributing the conduction of the lightning currents between the paint, and a lightweight conventional protection, without harming the finished surface condition despite a finish paint layer of reduced thickness.

FIGS. 2a and 2b illustrate the effectiveness of the invention which has been demonstrated by lightning tests on test specimens.

In FIG. 2a, which is a highly enlarged photograph of a micro-section of the test specimen on the side of the protected surface of the composite material, the wire mesh of electrically conductive material 31 appears in a cross section as a discontinuous layer (pale colored in the micro-section), and the conductive paint 32 and the finish paint 34 can be easily identified, as well as the plies of composite material 2 closest to the surface concerned, which are clearly different in the micro-section owing to the different orientation of the fibers of each ply.

FIG. 2b shows the surface of the specimen representative of the part 1 of composite material covered with a metallization according to the invention and which has been subjected to a lightning impact in the laboratory.

In this test, the specimen is subjected to a lightning impact along a wave profile D+B+C according to European standard ED-84.

Whereas such an impact would damage an unprotected composite material, FIG. 2a reveals only superficial traces of an area 41 in FIG. 2a, about 200 mm in diameter, around the location 4 of the lightning impact on the specimen surface.

The structural portion of composite material 2 was found to suffer no damage, even though the metallization of the surface is much more lightweight than in conventional metallizations.

The conductive material of the wire mesh 32 shows traces of evaporation on a reduced area and the conductive paint layer 32 has evaporated over about 200 mm, the diameter of the area 41 surrounded by a broken circle in FIG. 2a.

The protection is applied by conventional techniques of depositing metal wire mesh on a composite structure and paints, without resorting to complex protective arrangements employing intermediate layers which are of no advantage with regard to their effect on the lightning currents.

1.-12. (canceled)

13. A part (1) comprising a structural portion of composite material (2), said composite material essentially comprising inorganic or organic fibers maintained in a hard, electrically insulating or low-conductive organic matrix, comprising, on one surface (21) of said structural portion, at least on one side of said part liable to be exposed to accumulations of electrical charges and/or to lightning impacts, a wire mesh (31), of an electrically conductive material, characterized in that the wire mesh covers a protected portion of the surface (21) of said structural portion to which surface said wire mesh is directly attached, and in that a layer of electrically conductive paint (32) is deposited on the part (1) so that the wire mesh (31) is located between the structural portion (2) of electrically insulating or low-conductive composite material and the layer of electrically conductive paint (32).

14. The part (1) as claimed in claim 13, comprising, between the wire mesh (31) and the layer of electrically conductive paint (32), a sizing and/or primer layer for protecting the wire mesh (31).

15. The part (1) as claimed in claim 13, in which the wire mesh is a bronze metal wire mesh.

16. The part (1) as claimed in claim 13, in which the wire mesh is a metal wire mesh made from copper or copper alloy.

17. The part (1) as claimed in claim 13, in which the wire mesh is a metal wire mesh made from aluminum or aluminum alloy.

18. The part (1) as claimed in claim 15, in which the metal wire mesh has a surface density of 30 to 100 g/m2.

19. The part (1) as claimed in claim 18, in which the metal wire mesh has a surface density of 70±10 g/m2.

20. The part (1) as claimed in claim 13, in which the electrical conductivity of the electrically conductive paint layer (32) is at least 0.0001 Siemens/m.

21. The part (1) as claimed in claim 13, comprising a finish paint layer (34) on the side of said part that is liable to be exposed to accumulations of electrical charges and/or lightning impacts.

22. The part (1) as claimed in claim 21, in which the thickness of the finish paint layer (34) is 20±5 μm on average.

23. The part (1) as claimed in claim 22, in which the cumulative thickness of the electrically conductive paint layer (32) and the finish paint layer (34) is 100±20 μm on average.

24. The part (1) as claimed in claim 14, in which the wire mesh is a bronze metal wire mesh.

25. The part (1) as claimed in claim 14, in which the wire mesh is a metal wire mesh made from copper or copper alloy.

26. The part (1) as claimed in claim 14, in which the wire mesh is a metal wire mesh made from aluminum or aluminum alloy.

27. The part (1) as claimed in claim 16, in which the metal wire mesh has a surface density of 30 to 100 g/m2.

28. The part (1) as claimed in claim 17, in which the metal wire mesh has a surface density of 30 to 100 g/m2.

29. The part (1) as claimed in claim 18, in which the metal wire mesh has a surface density of 30 to 100 g/m2.

30. The part (1) as claimed in claim 14, in which the electrical conductivity of the electrically conductive paint layer (32) is at least 0.0001 Siemens/m.

31. The part (1) as claimed in claim 15, in which the electrical conductivity of the electrically conductive paint layer (32) is at least 0.0001 Siemens/m.

32. The part (1) as claimed in claim 16, in which the electrical conductivity of the electrically conductive paint layer (32) is at least 0.0001 Siemens/m.
